(19) United States
(12) Patent Application Publication
(10) Pub. No.: US 2026/0020279 A1
(43) Pub. Date: Jan. 15, 2026

(54) TRENCH MOSFET AND MANUFACTURING METHOD OF THE SAME

(71) Applicant: SILTRONIS Inc., TAOYUAN CITY (TW)

(72) Inventors: Yi-Fan Wu, TAOYUAN CITY (TW); Jiong-Guang Su, TAOYUAN CITY (TW); Hung-Wen Chou, TAOYUAN CITY (TW)

(73) Assignee: SILTRONIS Inc., TAOYUAN CITY (TW)

(21) Appl. No.: 18/798,764

(22) Filed: Aug. 8, 2024

(30) Foreign Application Priority Data
Jul. 9, 2024 (TW) 113125650

(51) Int. Cl. H01L 29/78; H01L 21/311; H01L 29/417; H01L 29/423; H01L 29/66

(52) U.S. Cl. CPC H10D 30/60; H01L 21/31111; H01L 21/31144; H10D 64/021; H10D 64/256; H10D 64/513

(57) ABSTRACT

A trench MOSFET includes a substrate, a gate structure, source regions, oxide spacers, a nitride cladding layer, an inner dielectric layer, a source contact, and a gate contact. The gate structure is disposed in a trench of the substrate and has a protruding top exposed from a surface of the substrate and having exposed sidewalls. The source regions are formed in the surface of the substrate on both sides of the gate structure. The oxide spacers are disposed on the exposed sidewalls of the protruding top. The nitride cladding layer conformally covers the oxide spacer and the surface of the substrate. The inner dielectric layer is deposited on the nitride cladding layer. The source contact window passes through the inner dielectric layer and the nitride cladding layer. The gate contact passes through the inner dielectric layer and the nitride cladding layer.

### CROSS-REFERENCE TO RELATED APPLICATION

This application claims the priority benefit of Taiwan application serial no. 113125650, filed on Jul. 9, 2024. The entirety of the above-mentioned patent application is hereby incorporated by reference herein and made a part of specification.

### BACKGROUND

### Technical Field

The disclosure relates to a technical improvement of a trench metal-oxide-semiconductor field-effect transistor (MOSFET), and in particular, to a trench MOSFET and a manufacturing method of the same.

### Description of Related Art

A trench metal-oxide-semiconductor field-effect transistor (MOSFET) is an element widely used in power semiconductor devices. Generally, a trench MOSFET includes a plurality of trench gates located on a substrate and a source and a drain disposed on two surfaces of the substrate. To electrically connect the source terminal of the trench MOSFET, a contact is formed most of the time to align with the substrate between the trench gates.

However, simply using the exposure in the lithography process for alignment is easily affected by the accuracy of the exposure machine, and result in misalignment in the formed contact. In particular, the contacts located on the silicon substrate will be shifted to various degrees during exposure, and result in uneven distribution of threshold voltage (Vth) across the entire wafer.

### SUMMARY

The disclosure provides a trench metal-oxide-semiconductor field-effect transistor (MOSFET) and a manufacturing method of the same through which contact offset caused by misalignment during exposure is prevented, and the Vth distribution of the entire wafer is thereby improved.

The disclosure provides a trench MOSFET including a substrate, a gate structure, source regions, oxide spacers, a nitride cladding layer, an inner dielectric layer, a source contact, and a gate contact. The gate structure is disposed in a trench of the substrate and has a protruding top exposed from a surface of the substrate and having exposed sidewalls. The source regions are formed in the surface of the substrate on both sides of the gate structure. The oxide spacers are disposed on the exposed sidewalls of the protruding top. The nitride cladding layer conformally covers the oxide spacers and the surface of the substrate. The inner dielectric layer is deposited on the nitride cladding layer. The source contact passes through the inner dielectric layer and the nitride cladding layer and contacts the source regions. The gate contact passes through the inner dielectric layer and the nitride cladding layer and contacts the gate structure.

In an embodiment of the disclosure, the ratio of a thickness of the nitride cladding layer to a height of the protruding top is positively correlated with the etching selectivity ratio of the nitride cladding layer to the inner dielectric layer.

In an embodiment of the disclosure, a height of the protruding top is positively correlated with a thickness of the oxide spacers located on the exposed sidewalls.

In an embodiment of the disclosure, the trench MOSFET further includes a metal layer disposed on the inner dielectric layer and connected to the source contact and the gate contact.

The disclosure further provides a manufacturing method of a trench MOSFET, and the method includes the following steps. A patterned hard mask is formed on a substrate to expose a portion of a surface of the substrate. The patterned hard mask is treated as an etching mask to remove a portion of the substrate to form at least one trench. A gate structure is formed in the at least one trench. The top surface of the gate structure is coplanar with the top surface of the patterned hard mask. The patterned hard mask is removed, so that the gate structure has a protruding top exposed from the surface of the substrate and having exposed sidewalls. Source regions are formed in the surface of the substrate on both sides of the gate structure. Oxide spacers are formed on the exposed sidewalls of the protruding top. A nitride cladding layer is conformally deposited on the oxide spacers and the surface of the substrate. An inner dielectric layer is formed on the nitride cladding layer. A source contact opening is formed in the inner dielectric layer and the nitride cladding layer, and the source regions in the substrate are exposed. A gate contact opening is formed in the inner dielectric layer and the nitride cladding layer, and the gate structure is exposed. A source contact and a gate contact are formed in the source contact opening and the gate contact opening.

In another embodiment of the disclosure, a remaining thickness of the patterned hard mask after forming the trench is substantially the same as the height of the protruding top of the gate structure.

In another embodiment of the disclosure, the steps of forming the gate structure include the following. A gate oxide layer is grown on the inner surface of the at least one trench, and a polycrystalline silicon material is deposited to fill the at least one trench, and the polycrystalline silicon material is etched back.

In another embodiment of the disclosure, the steps of forming the source contact opening and the gate contact opening include the following. The inner dielectric layer is etched until the nitride cladding layer is exposed. The nitride cladding layer is etched until the source regions and the gate structure are exposed.

In another embodiment of the disclosure, the method further includes the following. After the nitride cladding layer is etched, the substrate of the source regions and the top portion of the gate structure are recessed.

To make the aforementioned features more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A to FIG. 1I are cross-sectional schematic views of a manufacturing process of a trench metal-oxide-semiconductor field-effect transistor (MOSFET) according to an embodiment of the disclosure.

### DESCRIPTION OF THE EMBODIMENTS

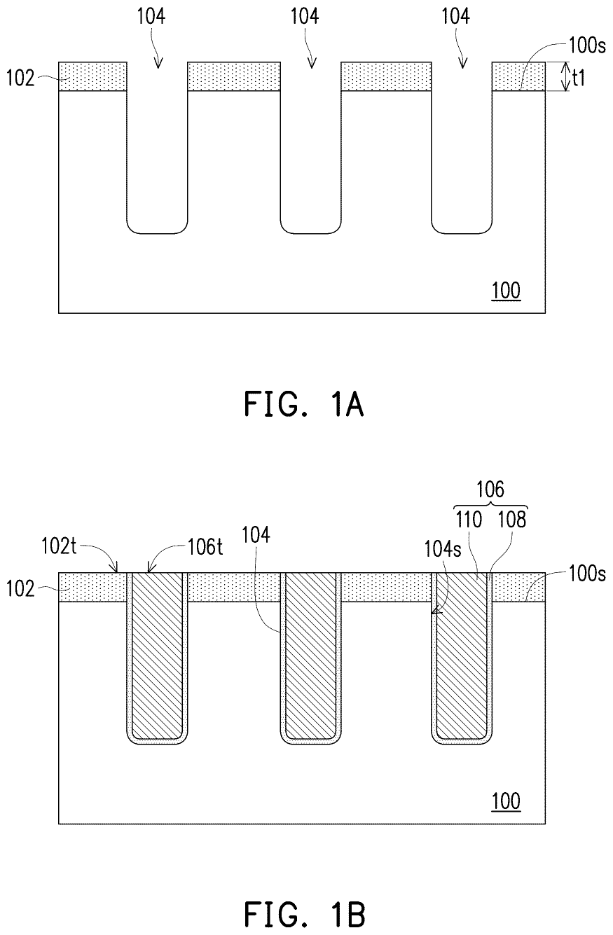

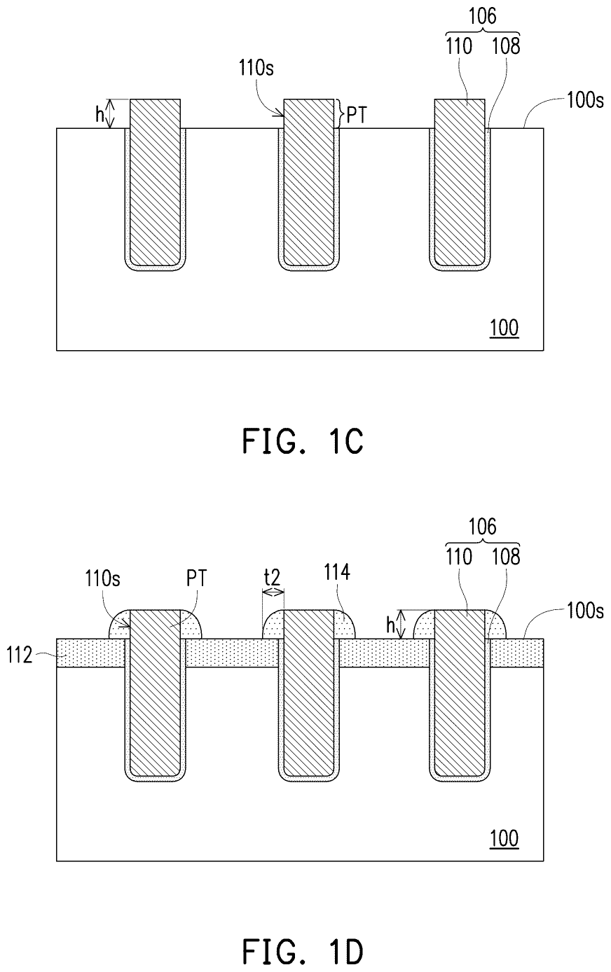

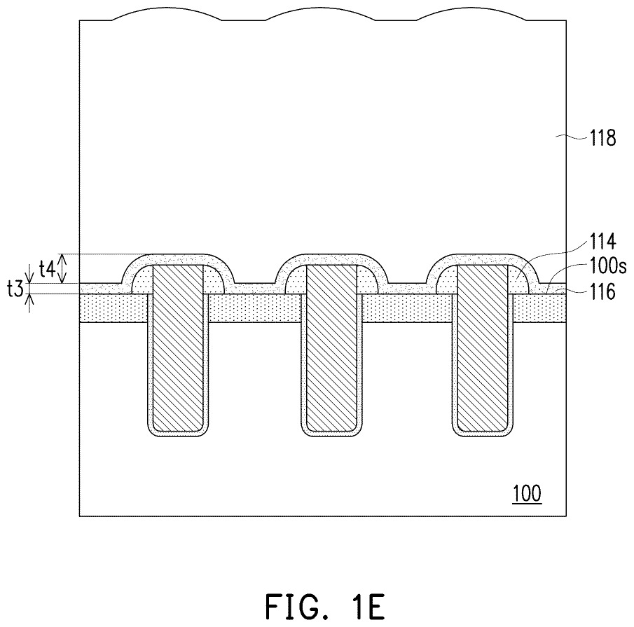

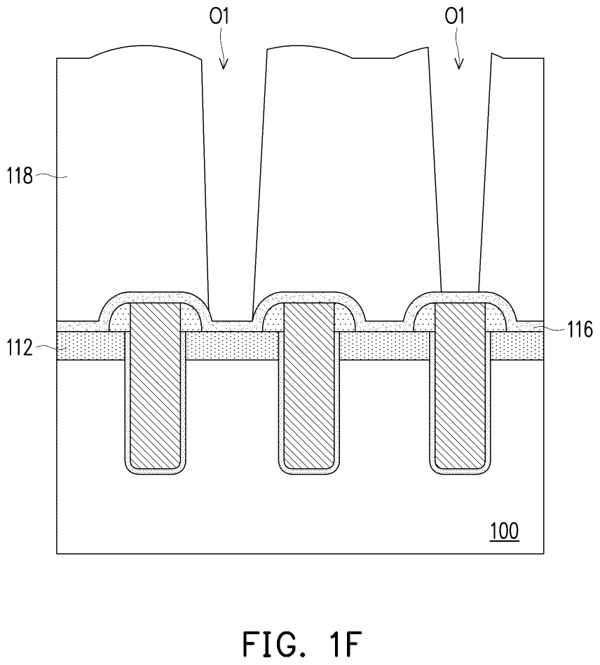

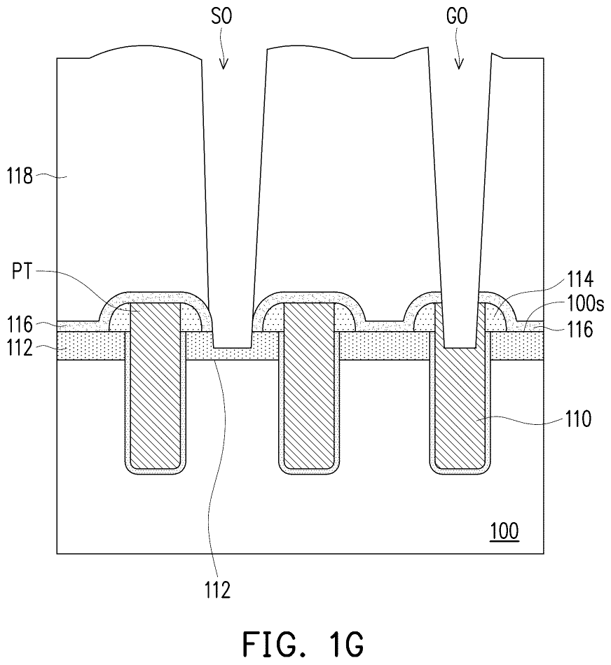

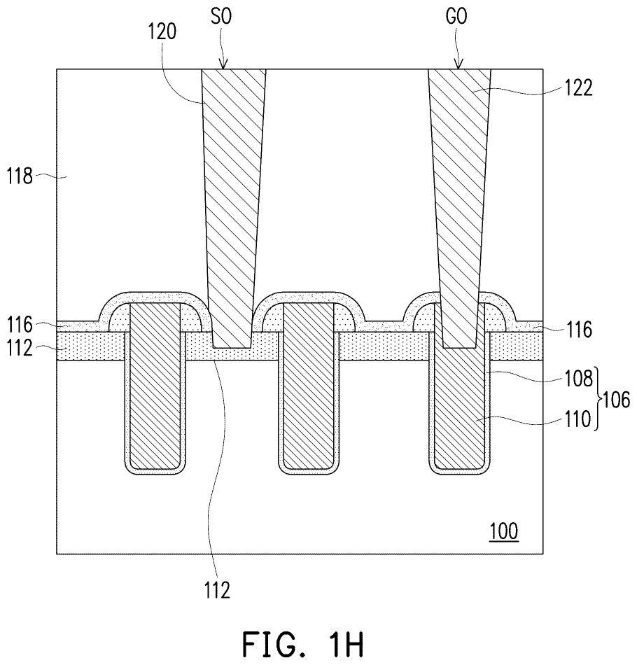

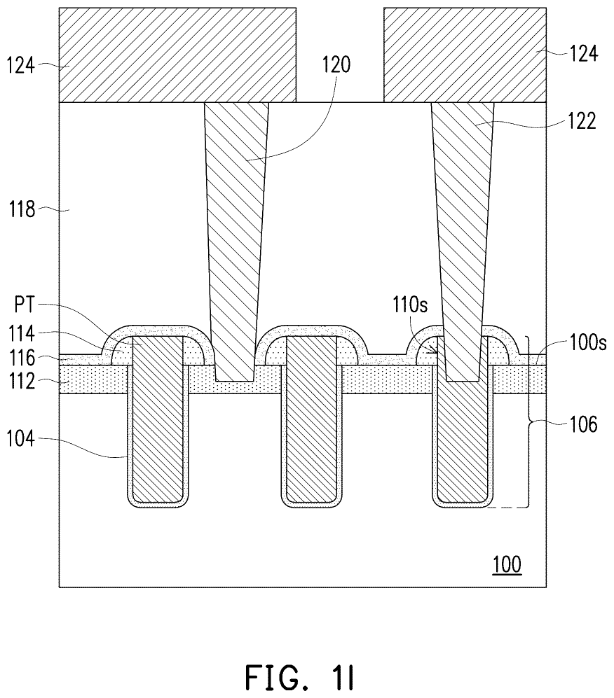

FIG. 1A to FIG. 1I are cross-sectional schematic views of a manufacturing process of a trench metal-oxide-semiconductor field-effect transistor (MOSFET) according to an embodiment of the disclosure.

With reference to FIG. 1A, a patterned hard mask 102 is formed on a substrate 100 to expose a portion of a surface 100s of the substrate 100. The steps of forming the patterned hard mask 102 may include but not limited to the following. An oxide layer is deposited on the substrate 100 first and then patterned by a photolithography process to obtain one layer of hard mask layer that is thicker than the patterned hard mask 102 in the FIGURE. In some embodiments, the patterned hard mask 102 may be a multi-layer structure. Next, the patterned hard mask 102 is treated as an etching mask to remove a portion of the substrate 100 to form a plurality of trenches 104. Since the hard mask is also consumed during the process of etching to form the trenches 104, the FIGURE shows a remaining thickness t1 of the patterned hard mask 102 after the trenches 104 are formed. In some embodiments, the thickness t1 of the patterned hard mask 102 is thicker than the normal hard mask generally used to form the trenches 104. This is because the hard mask generally used to form the trenches 104 is typically removed after the trenches are formed, so it is only necessary to deposit a thickness sufficient to maintain the thickness during the process of etching the trenches. However, in the disclosure, a thicker patterned hard mask 102 is required to make gates to be subsequently formed in the trenches 104 protrude from the surface 100s of the substrate 100, so the remaining thickness t1 of the patterned hard mask 102 is relatively thick. For instance, if an etching selectivity ratio of silicon oxide to silicon is 1:10, to form a 0.9 μm trench 104 in the substrate 100 and to make the gate subsequently formed in the trench 104 protrude 0.2 μm from the surface 100s of the substrate 100, the original thickness of the patterned hard mask 102 before the trench 104 is formed needs to be approximately 3000 Å, and the rest may be deduced by analogy.

Next, with reference to FIG. 1B, a gate structure 106 is formed in the trench 104, where the top surface 106t of the gate structure 106 is coplanar with the top surface 102t of the patterned hard mask 102. The steps of forming the gate structure 106 may include but not limited to the following. A gate oxide layer 108 is grown on the inner surface 104s of the trench 104 first, and then a polycrystalline silicon material 110 is deposited to fill the trench 104, and the polycrystalline silicon material 110 is etched back.

Next, with reference to FIG. 1C, the patterned hard mask 102 in FIG. 1B is removed, so that the gate structure 106 has a protruding top PT exposed from the surface 100s of the substrate 100 and having exposed sidewalls 110s. In some embodiments, the thickness t1 of the patterned hard mask 102 in FIG. 1A remaining after the trench 104 is formed is substantially the same as the height h of the protruding top PT of the gate structure 106. Therefore, the height h of the protruding top PT may be controlled through the thickness t1 of the patterned hard mask 102.

After that, with reference to FIG. 1D, source regions 112 are formed in the surface 100s of the substrate 100 on both sides of the gate structure 106. For instance, N-type dopants are implanted into the substrate 100 by an ion implantation process, but the disclosure is not limited thereto. Next, oxide spacers 114 are formed on the exposed sidewalls 110s, where the material of the oxide spacers 114 is, for example, non-doped silicate glass (NSG) or other suitable materials. The steps of forming the oxide spacers 114 may include but not limited to the following. First, NSG is deposited on the surface 100s of the substrate 100 to cover the protruding top PT, and then the NSG is etched back until the surface 100s is exposed. Further, a thickness t2 may be adjusted through the height h of the protruding top PT and the NSG forming process. In some embodiments, the height h of the protruding top PT is positively correlated with the thickness t2 of the oxide spacers 114 located on the exposed sidewalls 110s.

Next, with reference to FIG. 1E, a nitride cladding layer 116 is conformally deposited on the oxide spacers 114 and the surface 100s of the substrate 100, where the material of the nitride cladding layer 116 is, for example, silicon nitride or other suitable nitrides. An inner dielectric layer 118 is then formed on the nitride cladding layer 116. The steps may include but not limited to the following. BPSG is deposited first and then reflowed. In addition, after the inner dielectric layer 118 is formed, a planarization process (such as CMP) may be performed to flatten the top portion of the inner dielectric layer 118.

In some embodiments, the ratio of the thickness t3 of the nitride cladding layer 116 to the bottom thickness t4 of the inner dielectric layer 118 is positively correlated with the etching selectivity ratio of the nitride cladding layer 116 to the inner dielectric layer 118. Herein, the bottom thickness t4 of the inner dielectric layer 118 is substantially equal to the height h of the protruding top PT in FIG. 1D. For instance, if the etching selectivity ratio of the nitride cladding layer 116 to the inner dielectric layer 118 is 1:10, the ratio of the thickness t3 of the nitride cladding layer 116 to the bottom thickness t4 of the inner dielectric layer 118 is at least 1:10. That is, under the aforementioned etching selectivity ratio condition, if the bottom thickness t4 of the inner dielectric layer 118 is 0.2 μm, the thickness t3 of the nitride cladding layer 116 is expected to be greater than 200 Å.

Next, with reference to FIG. 1F, in order to form a contact opening in the inner dielectric layer 118 and the nitride cladding layer 116, a patterned photoresist or mask layer (not shown) may be formed on the inner dielectric layer 118 first. The inner dielectric layer 118 is then etched until the nitride cladding layer 116 is exposed to form an opening O1. Due to the high etching selectivity ratio between the inner dielectric layer 118 and the nitride cladding layer 116, even if a position of the opening O1 is offset as shown in the FIGURE, a source opening formed subsequently may be corrected back to a center position, and the gate opening won't etch through the gate structure 106.

After that, with reference to FIG. 1G, the exposed nitride cladding layer 116 is etched to form a source contact opening SO exposing the source regions 112 in the substrate 100, and the etching may be continued to recess the exposed substrate 100. In the same etching process, the exposed nitride cladding layer 116 on the polycrystalline silicon material 110 may also be etched to form a gate contact opening GO, and the etching may also be continued to recess the exposed polycrystalline silicon material 110.

Double-layer spacers, namely the oxide spacers 114 and the nitride cladding layer 116, are disposed on both sides of the protruding top PT, and these two-layer spacers have an obvious selectivity ratio during etching to form the source contact opening SO. Therefore, the influence from the offset during exposure to form the source contact opening SO may be reduced, so that the source contact opening SO is accurately located in the center, and the purpose of self-alignment is thereby achieved.

With reference to FIG. 1H, a source contact 120 and a gate contact 122 are formed in the source contact opening SO and the gate contact opening GO. The steps of forming the source contact 120 and the gate contact 122 may include but not limited to the following. Tungsten (W) is filled in it, and then CMP or etching back of the tungsten is performed. The source contact 120 and the gate contact 122 may be made of other metals besides tungsten. Besides, to improve electrical properties, before the source contact 120 and the gate contact 122 are formed, a heavily doped region, such as a P+ region, may be formed in the substrate 100 (e.g., the source regions 112) below the source contact opening SO.

In FIG. 1I, a metal layer 124 is formed on the inner dielectric layer 118 and is connected to the source contact 120 and the gate contact 122. Although the source contact 120 and the gate contact 122 are shown in the same cross section in the FIGURE, this is only used to illustrate how the process of forming the source contact 120 is performed together with the process of forming the gate contact 122. In actual element design, the source contact 120 and the gate contact 122 may be disposed at different cross sections.

The trench MOSFET in FIG. 1I includes the substrate 100, the gate structure 106, the source regions 112, the oxide spacers 114, the nitride cladding layer 116, the inner dielectric layer 118, the source contact 120, and the gate contact 122. The gate structure 106 is disposed in the trench 104 of the substrate 100, and the protruding top PT of the gate structure 106 is exposed from the surface 100s of the substrate 100. The source regions 112 are formed in the surface 100s of the substrate 100 on both sides of the gate structure 106. The oxide spacers 114 are disposed on the exposed sidewalls 110s. The nitride cladding layer 116 conformally covers the oxide spacers 114 and the surface 100s of the substrate 100. The inner dielectric layer 118 is disposed on the nitride cladding layer 116. The source contact 120 passes through the inner dielectric layer 118 and the nitride cladding layer 116 and contacts the source regions 112. The gate contact 122 passes through the inner dielectric layer 118 and the nitride cladding layer 116 and contacts the gate structure 106.

In view of the foregoing, in the disclosure, a gate structure that protrudes further from the substrate than a conventional trench gate is used, and a double-layer spacer design is arranged on the sidewall thereof. Further, these two layers of spacers have an obvious selectivity ratio during etching to form the contact openings. This allows the contact openings to be self-aligned between the gate structures, so that the Vth distribution of the entire wafer is improved.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A trench metal-oxide-semiconductor field-effect transistor (MOSFET), comprising:
a substrate having at least one trench;
a gate structure disposed in the at least one trench and having a protruding top exposed from a surface of the substrate and having exposed sidewalls;
source regions formed in the surface of the substrate on both sides of the gate structure;
oxide spacers disposed on the exposed sidewalls of the protruding top;
a nitride cladding layer conformally covering the oxide spacer and the surface of the substrate;
an inner dielectric layer deposited on the nitride cladding layer;
a source contact passing through the inner dielectric layer and the nitride cladding layer and contacting the source regions; and
a gate contact passing through the inner dielectric layer and the nitride cladding layer and contacting the gate structure.

2. The trench MOSFET according to claim 1, wherein a ratio of a thickness of the nitride cladding layer to a height of the protruding top is positively correlated with an etching selectivity ratio of the nitride cladding layer to the inner dielectric layer.

3. The trench MOSFET according to claim 1, wherein a height of the protruding top is positively correlated with a thickness of the oxide spacers located on the exposed sidewalls.

4. The trench MOSFET according to claim 1, further comprising: a metal layer disposed on the inner dielectric layer and connected to the source contact and the gate contact.

5. A manufacturing method of a trench MOSFET, comprising:
forming a patterned hard mask on a substrate to expose a portion of a surface of the substrate;
treating the patterned hard mask as an etching mask to remove a portion of the substrate to form at least one trench;
forming a gate structure in the at least one trench, wherein a top surface of the gate structure is coplanar with a top surface of the patterned hard mask;
removing the patterned hard mask, so that the gate structure has a protruding top exposed from the surface of the substrate and having exposed sidewalls;
forming source regions in the surface of the substrate on both sides of the gate structure;
forming oxide spacers on the exposed sidewalls of the protruding top;
conformally depositing a nitride cladding layer on the oxide spacer and the surface of the substrate;
forming an inner dielectric layer on the nitride cladding layer;
forming a source contact opening in the inner dielectric layer and the nitride cladding layer and exposing the source regions in the substrate;
forming a gate contact opening in the inner dielectric layer and the nitride cladding layer and exposing the gate structure; and
forming a source contact and a gate contact in the source contact opening and the gate contact opening.

6. The manufacturing method of the trench MOSFET according to claim 5, wherein a remaining thickness of the patterned hard mask after forming the at least one trench is substantially the same as a height of the protruding top of the gate structure.

7. The manufacturing method of the trench MOSFET according to claim 5, wherein the steps of forming the gate structure comprise:
growing a gate oxide layer on an inner surface of the at least one trench;
depositing a polycrystalline silicon material to fill the at least one trench; and
etching back the polycrystalline silicon material.

8. The manufacturing method of the trench MOSFET according to claim 5, wherein the steps of forming the source contact opening and the gate contact opening comprise:
etching the inner dielectric layer until the nitride cladding layer is exposed; and
etching the nitride cladding layer until the gate structure and the source regions are exposed.

9. The manufacturing method of the trench MOSFET according to claim 8, further comprising recessing the substrate of the source regions and a top portion of the gate structure after the nitride cladding layer is etched.
